(19) United States
(12) Patent Application Publication
(10) Pub. No.: US 2013/0061931 A1
(43) Pub. Date: Mar. 14, 2013

(54) EFFICIENT ORGANIC SOLAR CELL USING CORE/SHELL METAL OXIDE NANOPARTICLES, AND METHOD FOR MANUFACTURING SAME

(71) Applicants: Dong Chan Lim, Seoul (KR); Kyu Hwan Lee, Gyeongsangnam-do (KR); Yongsoo Jeong, Gyeongsangnam-do (KR); Jae-Hong Lim, Gyeongsangnam-do (KR); Sun Young Park, Gyeongsangnam-do (KR); Young Dok Kim, Gyeonggi-do (KR)

(72) Inventors: Dong Chan Lim, Seoul (KR); Kyu Hwan Lee, Gyeongsangnam-do (KR); Yongsoo Jeong, Gyeongsangnam-do (KR); Jae-Hong Lim, Gyeongsangnam-do (KR); Sun Young Park, Gyeongsangnam-do (KR); Young Dok Kim, Gyeonggi-do (KR)

(73) Assignee: KOREA INSTITUTE OF MACHINERY AND MATERIALS, Daejeon (KR)

(21) Appl. No.: 13/697,756

(22) PCT Filed: Sep. 28, 2011
(86) PCT No.: PCT/KR11/07146

§ 371 Date: Nov. 13, 2012

(30) Foreign Application Priority Data
Oct. 27, 2010 (KR) 1020100105250

(51) Int. Cl. H01L 51/46; H01L 51/48

(52) U.S. Cl. 136/263; 438/82; 257/E51.026

(57) ABSTRACT

The present invention relates to a photoactive layer solution for an efficient organic solar cell including core/shell metal oxide nano-particles, to a method for manufacturing same, and to an organic solar cell including the photoactive layer solution and to a method for manufacturing same. Uniform coating of a substrate having a large area is difficult using the existing PEDOT:PSS. However, using the photoactive layer solution according to the present invention enables P-type metal oxide nano-particles to be directly dispersed on the photoactive layer, thereby having efficiency similar to the existing layer-by-layer (LbL)-type organic solar cell, and enabling a reduction in costs, since there is no need to deposit a separate p buffer layer such as PEDOT:PSS, and the organic solar cell to be manufactured by means of just a simple wet process. Also, application products can be selected through various types of coating methods.

### BACKGROUND OF THE INVENTION

1. Field of the Invention

The present invention relates to a method of manufacturing a photoactive layer solution for an efficient organic solar cell including core/shell metal oxide nano-particles, a photoactive layer solution, an organic solar cell including the photoactive layer solution, and a method of manufacturing the same.

2. Description of the Related Art

Recently, clean-alternative energy is in great demand due to soaring oil price and environmental pollution, and the world makes an enormous effort to develop alternative energy source such as a hydrogen/fuel cell, solar cell, wind power and so on. Particularly for the past five years, the world's demand for solar cell was rapidly increased, with more than 35% increase per year and in 2006, the total output became almost 2.5 GW (i.e., 1.5 GW by installation output), hitting 15 billion dollars. Accordingly, it is forecasted that a solar cell generates huge market and chases currently expanded semiconductor market over the next ten years. Meanwhile, this radical expansion of the world's solar cell industry causes over-raised demand for crystalline silicon solar cells which are commonly utilized solar cell in present days, causing unbalanced supply of silicon materials of the crystalline silicon solar cells. Accordingly, it is crucial to develop an organic thin layer solar in order to overcome the economical limitation and imbalance of supply and demand with respect to in-organic silicon material.

An organic thin film solar cell drew public attention since C. Tang of Eastman Kodak Company had initially introduced possibility for commercializing a practical solar cell having heterojunction silicon structure by using CuPC (copper pthalocyanine) and PTCD (perylene tetracarboxylic derivative) in 1986. Although around 1% of efficiency was presented in early period, through many researches in 2000s regarding the organic thin film solar cell, maximum 7.5% of energy conversion efficiency has been achieved so far. Many experts forecast if energy level of an organic semiconductor and property thereof is controlled well, theoretically 10% of energy conversion efficiency would be achievable. This forecast makes others hoped for a brighter future for commercialization of an organic thin film cell.

In this regard, developed countries give their national supports for the next generation solar cell, such as, ‘Next Generation Solar Energy Projects’ in U.S., ‘ATHLET (Advanced Thin Film Technologies for Cost Effective Photovoltaics) program’ in Europe, and ‘R&D for Next Generation PV Systems’ in Japan. In fact, some companies such as Siemens (EU), Konarka (US), Flextronic (US) already have noticed the importance and practical use of an organic thin film solar cell, so that they have been developing and proceeding the projects for commercializing the organic thin film solar cell.

Meanwhile, a conventional OPV (Organic Photovoltaic cell) has a structure presented in FIG. 1. A transparent conductive substrate (ITO) is coated with P-type conductive materials (i.e., PEDOT:PSS), the PEDOT:PSS is coated with a photoactive layer, and a LiF/Al electrode is placed on the photoactive layer. P3HT, a polymer absorbing sun light and creating electrons and holes, and PCMB, a C60 inducer assisting separation and movement of the created electrons, are commonly used for the photoactive layer. The coating process of the photoactive layer is performed by many processes consisting of spin coating, spray coating, doctor blading or dipping, but vacuum equipment is used to deposit the ITO and LiF/Al electrode.

Korean Patent No. 2004-0089569 (KR 2004-0089569) relates to a photoelectric conversion device fabrication method, photoelectric conversion device, electronic apparatus manufacturing method, electronic apparatus, metal film formation method and layer structure, and semiconductor fine particle and layer structure. More specifically, KR 2004-0089569 proposes a photoelectric conversion device including a semiconductor electrode consisting semiconductor fine particles and a metal film acted as a counter electrode forms polyethylenedioxythiophene (PEDOT)/poly styrene sulfonic acid (PSS) film to improve adhesion of the metal film toward metal oxide film remarkably and to prevent the impurity of the metal film (i.e., a counter electrode) from different forms of metals. Also, the semiconductor electrode consisting semiconductor fine particles can be formed on the metal oxide film by low temperature treatment and the photoelectric conversion device can be obtained by preventing elution of the metal oxide film.

However, since PEDOT:PSS deposited on the ITO has acidic property, the problem involved with the deterioration of ITO substrate property appears. Accordingly, to address this problem, development of neutral-type PEDOT:PSS or deposit of a new form of P-type conductive film such as metal oxide thin film having similar electrical property to the neutral-type PEDOT:PSS, have been studied.

U.S. Patent No. 2005-0251597 and Korean Patent No. 2006-0120378 describe some examples of using ionomers in which main and branch chains thereof are substituted by fluorine group after doping to conductive polymer. However, since most of carbon group within the main and branch chains of the ionomer is substituted by fluorine group, the dispersing time in water is shortened. Accordingly, when conductive polymer is manufactured with this characteristics, serious agglomeration is occurred even when the repeating unit of the conductive polymer becomes a little bit longer, and when the ionomers are used to manufacture thin film by spin coating, uniformity of the manufactured thin film deteriorates.

Accordingly, in order to manufacture an efficient organic solar cell, the inventors of the present invention introduced a method of coating P-type metal nano-particles with N-type metal oxide and adding the particles into photoactive layer solution to manufactured an organic solar cell and confirmed that the P-type buffer layer is efficiently performed, and completed the present invention.

### SUMMARY OF THE INVENTION

The present invention aims to provide a photoactive layer solution for an efficient organic solar cell including core/shell metal oxide nano-particles and a method of manufacturing the same.

Also, the present invention aims to provide an organic solar cell including the photoactive layer solution and a method of manufacturing the same.

In order to achieve the object explained above, the present invention provides a method of manufacturing a photoactive layer solution for an efficient organic solar cell including core/shell metal oxide nano-particles, the method comprising steps of: forming core/shell structure by coating P-type metal nano-particles with N-type metal oxide (step 1); dispersing core/shell structured P-type metal nano-particles coated with N-type metal oxide of step 1 into dispersion solution (step 2); and adding a solution with dispersed core/shell structured P-type metal nano-particles coated with N-type metal oxide of step 2 into a mixture of P3HT (Poly(3-Hexylthiophene)) and PCBM (Phenyl-C61-butyric acid methyl ester) (step 3).

Also, the present invention provides a photoactive layer solution for an efficient organic solar cell including core/shell metal oxide nano-particles having P-type metal nano-particles coated with N-type metal oxide.

Further, the present invention provides an organic solar cell including the photoactive layer for an efficient organic solar cell having the core/shell metal oxide nano-particles and a method of manufacturing the same.

Furthermore, the present invention provides an electronic device including a photoactive layer solution for an efficient organic solar cell having the core/shell metal oxide nano-particles.

Although the substrate having a large area is uniformly coated with existing PEDOT:PSS with difficulty, using photoactive layer solution according to the present invention enables P-type metal oxide nano-particles to be directly dispersed on the photoactive layer, thereby having efficiency similar to the existing layer-by-layer (LBL) typed organic solar cell, enabling a reduction in costs, since not only that there is no need to deposit another P buffer layer such as PEDOT:PSS but also the organic solar cell is manufactured by means of just a simple wet process. Also, application products can be selected through various types of coating methods.

### BRIEF DESCRIPTION OF THE DRAWINGS

FIG. 1 presents mimetic diagrams illustrating a conventional OPV;

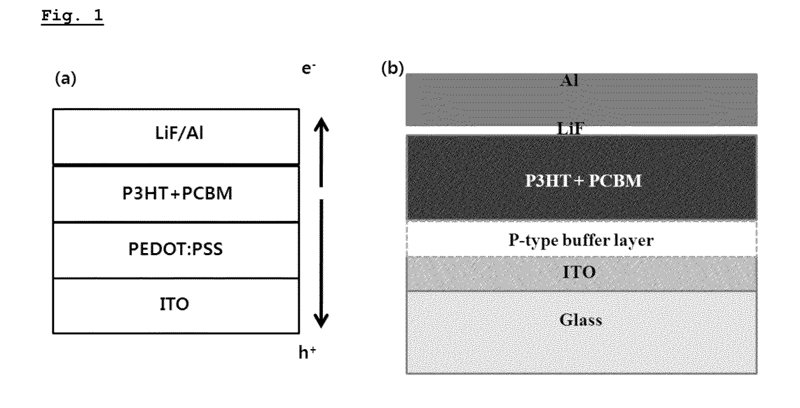

FIG. 2 presents mimetic diagrams illustrating an organic solar cell according to the present invention;

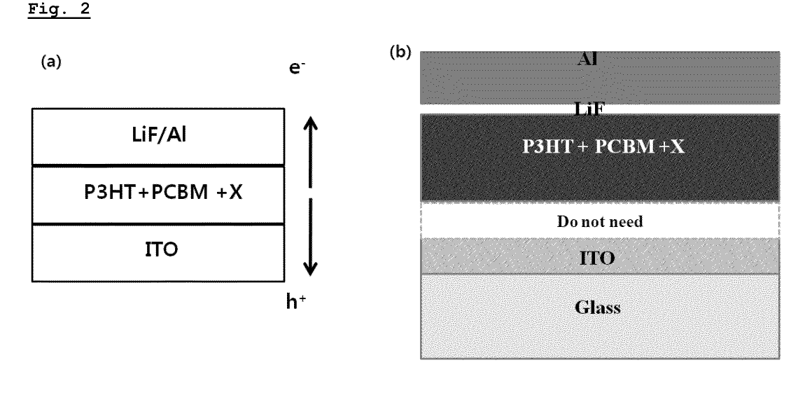

FIG. 3(a) presents a mimetic diagram illustrating an organic solar cell manufactured in Comparative Example 1, and FIG. 3(b) presents a graph representing photoelectric conversion property of the organic solar cell;

FIG. 4(a) presents a mimetic diagram illustrating an organic solar cell manufactured in Comparative Example 2, and FIG. 4(b) presents a graph representing photoelectric conversion property of the organic solar cell;

FIG. 5(a) presents a mimetic diagram illustrating an organic solar cell manufactured in Examples 8-11 and FIG. 5(b) presents a graph representing photoelectric conversion property of the organic solar cell;

FIG. 6(a) presents a mimetic diagram illustrating an organic solar cell manufactured in Comparative Examples 3-6, and FIG. 6(b) presents a graph representing photoelectric conversion property of the organic solar cell;

FIG. 7(a) presents a mimetic diagram illustrating an organic solar cell manufacture in Examples 9 and 15 and FIG. 7(b) presents a graph representing photoelectric conversion property of the organic solar cell;

FIG. 8(a) presents a mimetic diagram illustrating an organic solar cell manufactured in Examples 9 and 12-14 and FIG. 8(b) presents a graph representing photoelectric conversion property of the organic solar cell;

FIG. 9(a) presents a mimetic diagram illustrating photoactive layer according to the present invention, FIG. 9(b) presents cross-sectional view illustrating a Si substrate coated with photoelectric layer, FIG. 9(c) presents magnified SEM image of the cross-sectional photoelectric layer; and FIG. 9(d)-(i) present the results of EDX mapping;

FIG. 10 presents graphs representing X-ray photoelectric spectroscope (XPS) results regarding NiO/TiOₓ;

FIG. 11(a) presents an energy band diagram of an organic solar cell manufactured Comparative Example 7; FIG. 11 (b) presents an energy band diagram of an organic solar cell manufactured by coating NiO thin film with P-type buffer layer and FIG. 11(c) presents an energy band diagram of an organic solar cell manufactured in Example 9; and

FIG. 12 presents a TEM image illustrating the surface of NiO nano-particles on which TiOₓ film is evenly formed.

### DETAILED DESCRIPTION OF EXEMPLARY EMBODIMENTS

Hereinafter, the present invention will be explained in greater detail.

The present invention provides a method of manufacturing a photoactive layer solution for an efficient organic solar cell including core/shell metal oxide nano-particles, including steps of: forming core/shell structure by coating P-type metal nano-particles with N-type metal oxide (step 1); dispersing core/shell structured P-type metal nano-particles coated with N-type metal oxide of step 1 into dispersion solution (step 2); and adding a solution with dispersed core/shell structured P-type metal nano-particles coated with N-type metal oxide of step 2 into a mixture of P3HT (Poly(3-Hexylthiophene)) and PCBM (Phenyl-C61-butyric acid methyl ester) (step 3).

Hereinafter, each step of the present invention will be explained in greater detail.

According to the present invention, step 1 is performed to form core/shell structure by coating P-type metal nano-particles with N-type metal oxide. The P-type metal nano-particles act as P-type buffer layer. The role of P-type conductive buffer layer is to not only assist movement of holes created on photoactive layer, but also prevent recombination of electrons and holes to maintain voltage constantly. Also, the shell structured N-type metal oxide assists P-type metal nano-particles to maintain a certain voltage.

The coating of step 1 is preferably performed by atomic layer deposition (ADL). Since atomic layer deposition uses accuracy of atomic level to deposit thin film, it is ideal technique for low-dimensional film. The atomic layer deposition is preferably performed according to Korean Patent No. 2010-0011647. According to the above-mentioned method, atomic layer deposition using saturated surface reaction of a gas precursor can be applied to powder sample, so that a thin and uniform film can be deposited on all powder.

When atomic layer deposition of step 1 is performed, the temperature is preferably 100-300° C. If temperature is under 100° C., a chemical-absorbed precursor is not oxidized properly. If temperature exceeds 300° C., the chemical-absorbed precursor is degraded by itself and chemical-vapor deposition is performed thereon; therefore, excessively thick film is manufactured.

According to the present invention, step 2 is performed to disperse core/shell structured P-type metal nano-particles coated with N-type metal oxide in step 1 into a dispersion solution. The dispersion solution of step 2 is preferably benzene compounds including dichlorobenzene and chlorobenzene, but is not limited thereto. Accordingly, any other adequate compound may be used as dispersion solution. If the dichlorobenzene is used, conductive polymers used as photoactive layer can be easily dissolved.

In the step 2, the dispersion solvent of core/shell structured P-type metal nano-particles coated with N-type metal oxide has preferably 0.1-20% of concentration. If concentration is under 0.1%, P-type conductive layer may not be functional and if concentration exceeds 20%, dispersion may be performed with difficulty.

According to the present invention, step 3 is performed to add a solution with dispersed core/shell structured P-type metal nano-particles coated with N-type metal oxide in step 2 into a mixture of P3HT (Poly(3-Hexylthiophene)) and PCBM (Phenyl-C61-butyric acid methyl ester). While a photoactive layer of a conventional OPV is manufactured by using bulk heterojunction in which P3HT (i.e., electron donor) and PCBM (i.e., electron acceptor) are mixed, a photoactive layer solution according to the present invention includes core/shell structured P-type metal nano-particles coated with N-type metal oxide; therefore, the photoactive layer solution also acts as a P-type conductive buffer layer.

Also, the present invention provides a photoactive layer solution for an efficient organic solar cell including core/shell metal oxide nano-particles having core/shell structured P-type metal nano-particles coated with N-type metal oxide.

By using a photoactive layer solution for an efficient organic solar cell including core/shell metal oxide nano-particles having core/shell structure P-type metal nano-particles coated with N-type metal oxide according to the present invention, an organic solar cell with high efficiency can be manufactured without a P-type buffer layer such as PEDOT:PSS. Accordingly, the separate coating process of P-type buffer layer such as PEDOT:PSS can be removed and an organic solar cell can be manufactured by means of just a simple wet process. Also, application products can be selected through various types of coating methods.

The core/shell structured P-type metal nano-particles coated with N-type metal oxide included in the photoactive layer solution, preferably have core/shell structure. If P-type metal nano-particles are only inserted in a photoactive layer, the P-type metal nano-particles cannot act as P-type buffer. However, if P-type metal nano-particles are coated with N-type metal oxide to have core/shell structure, the P-type metal nano-particles act as P-type buffer layer since higher work function is formed.

The core/shell structured P-type metal nano-particles coated with N-type metal oxide included in the photoactive layer solution, is preferably NiO/TiOₓ, wherein x is 0.5-2. A ferromagnetic substance (i.e., Nickel (Ni)) is oxidized to become NiO which is an anti-ferromagnetic substance. This nickel oxide has excellent electrical, chemical, magnetic, and optical stability. More specifically, since the nickel oxide has anti-ferromagnetic property and wide bandgap (i.e., 3.6-4.0 eV), high transmission rate is appeared in the absorbing area of photoactive layer of an organic solar cell, and since HOMO (highest Occupied Molecular Orbital) level (˜5.1 eV) of P3HT, which is commonly used as a photoactive layer and Fermi level (˜4.9 eV) of NiO, are similar to each other, low resistance is appeared by ohmic contact between transparent electrode ITO and photoactive layer; therefore, an organic solar cell having high photoelectric conversion efficiency can be manufactured. Also, TiOₓ is known as an N-type conductor to fill up the holes. However, according to the present invention, the TiOₓ is coated in tens of nm, so that instead of functioning as N-type conductor, this TiOₓ only functions as a barrier maintaining voltage when P-type metal nano-particles are applied to an organic solar cell device.

The P-type metal nano-particles coated with N-type metal oxide included in the photoactive layer solution, is preferably 10-50 nm in size. If the P-type metal nano-particles coated with N-type metal oxide is under 10 nm, it is currently difficult to manufacture large quantity of nano-powder and if the P-type metal nano-particles coated with N-type metal oxide exceeds 50 nm, all the particles are filtered through the solution filtering process included in an organic solar cell manufacturing method.

Further, the present invention provides an efficient organic solar cell including core/shell metal oxide nano-particles including a transparent substrate; a transparent conductive oxide (anode); a photoactive layer including core/shell structured P-type metal nano-particles coated with N-type metal oxide; and a metal electrode (cathode).

Although an organic solar cell including a transparent substrate; a transparent conductive oxide (anode); a photoactive layer including core/shell structured P-type metal nano-particles coated with N-type metal oxide; and a metal electrode (cathode), does not include P-type buffer PEDOT:PSS or NiO thin film which is included in a conventional OPV, the organic solar cell has similar efficiency to a conventional OPV. Also, since an organic solar cell according to the present invention does not use P-type buffer layer, the problems of a conventional OPV involved in significant deterioration of ITO substrate caused due to acidic property of a conventional P-type buffer layer PEDOT:PSS; high costs of vacuum coating for the P-type NiO thin film buffer layer; and rapid electric property change of the P-type NiO thin film buffer layer after coating and exposure to air, are solved.

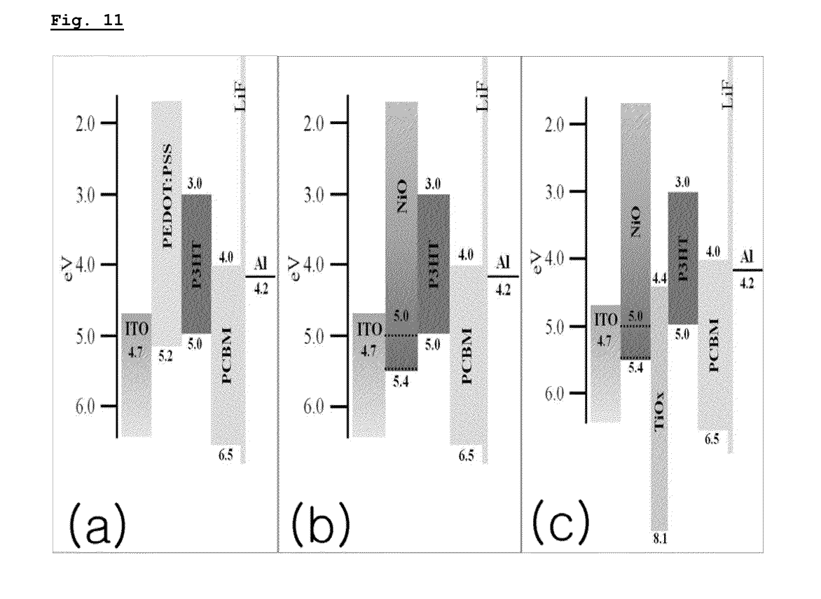

Referring to FIG. 11, the present invention will be explained in greater detail. FIG. 11 presents band diagrams connecting generally well known energy band according to layering order. FIG. 11(a) presents a band diagram of PEDOT:PSS typed organic solar cell, FIG. 11(b) presents a band diagram of an organic solar cell manufactured by using NiO thin film as P-type buffer layer, and FIG. 11(c) presents a band diagram of an organic solar cell manufactured by using core/shell metal oxide nano-particles according to the present invention.

In general, voltage of an organic solar cell depends on the difference between HOMO level of P3HT and LUMO level of PCBM. Voltage of the organic solar cell is 1-1.2 V, but inner resistance of the cell and decrease of anode and cathode voltage causes the voltage to be about 0.5-0.6 V. Referring to FIG. 11(a) and (b), if PEDOT:PSS and NiO thin film are vapor-deposited on the separate buffer layer, respectively, energy level is between 5.0 and 5.4 eV and this blocks recombination of interface to maintain voltage constantly.

However, although the same NiO is used, if powder formed NiO is inserted in photoactive layer, NiO does not act as a P-type buffer layer. Herein, if NiO nano-particles having core/shell structure is used after coating with TiOₓ, since higher work function is formed, the NiO nano-particles can act as P-type buffer layer. Although TiOₓ is generally well known as an N-type conductor to fill up the hole, considering that P-type metal nano-particles are thinly coated with TiOₓ through ALD according to the present invention, the TiOₓ rather works as a buffer to maintain voltage instead of an N-type conductor.

Referring to FIG. 11(c), holes are moved from HOMO level of P3HT to HOMO level of NiO, but if HOMO level of NiO is close to LUMO level of P3HT, recombination possibility of electrons and holes is increased. Accordingly, it is better that NiO level is close to 5.4 rather than to 5.0. If NiO is used as a separate thin film layer, NiO has enough 5.0-5.4 energy level, on the other hand, if NiO exists within photoactive layer, NiO cannot perform its own function. Herein, if TiOₓ having much larger HOMO level is used for coating through ADL method, NiO level is affected by TiOₓ level and shows high HOMO level as well as a separate thin film.

Thickness of a photoactive layer coating film including core/shell structured P-type metal nano-particles coated with N-type metal oxide is preferably 100-400 nm. Herein, the highest efficiency is presented. More specifically, if thickness of the coating film is under 100 nm, the creation of electrons is reduced due to the reduction of photoabsorption amount. If thickness of the coating film exceeds 400 nm, it takes relatively long time to move electrons and holes created from photoactive layer to both electrodes, so that electron-hole recombination possibility is increased.

Furthermore, the present invention provides a method of manufacturing an efficient organic solar cell including core/shell metal oxide nano-particles, the method comprising steps of: coating a transparent substrate with transparent conductive oxide (step a); coating photoactive layer including core/shell structured P-type metal nano-particles coated with N-type metal oxide on the transparent substrate with transparent conductive oxide coated thereon in step a) (step b); drying the photoactive layer coated in step b) (step c); performing heat treatment for the substrate dried in step c) (step d); and depositing electrode on the heat treated substrate of step d) (step e).

Hereinafter, each step of the present invention will be explained in greater detail.

According to the present invention, step a) is performed to coat a transparent substrate with transparent conductive oxide. The transparent conductive oxide is preferably ITO (indium tin oxide). ITO is a material having high work function and used as anode. Any material may be used as the transparent conductive oxide provided that the material has high work function and may be used as anode such as ITO.

According to the present invention, step b) is performed to coat photoactive layer including core/shell structured P-type metal nano-particles coated with N-type metal oxide on the transparent substrate with transparent conductive oxide coated thereon in step a). The coating is preferably performed by one method selected from a group consisting of spin coating, spray coating, dip coating and doctor blading.

According to the present invention, step c) is performed to dry the photoactive layer coated in step b). The drying is preferably natural drying at room temperature, but not limited thereto.

According to the present invention, step d) is performed to heat the substrate dried in step c). Through the heat treatment, strong inter-reaction between the chains of P3HT included in photoactive layer is occurred and PCBM is uniformly dispersed inside of P3HT. Accordingly, absorption strength is increased in the red-shift and visible ray of absorption spectrum. Also, core/shell structured P-type metal nano-particles coated with N-type metal oxide can be uniformly dispersed on photoactive layer through heat treatment. The heat treatment is preferably performed at 130-170° C., and more preferably, at 150°.

The heat treatment is preferably performed at 150° C. Crystallinity of conductive polymer plays major role in creation and movement of electrons. If heat treatment is performed under 150° C., crystallinity of conductive polymer may deteriorate and if the heat treatment is performed more than 150° C., polymers are dissolved and deterioration of crystallinity may be occurred.

According to the present invention, step e) is performed to vapor-deposit electrode on the heat treated substrates of step d). A cathode electrode may include lithium fluoride (LiF)/aluminum (Al), but if work function of a cathode material is lower than anode material, the cathode material is not limited thereto. Lithium fluoride (LiF)/Aluminum (Al) is deposited on the heat treated substrate of step d) with thermal evaporator.

Also, an electronic device including a photoactive layer solution for an efficient organic solar cell having core/shell metal oxide nano-particles according to the present invention is provided.

If a photoactive layer solution for efficient organic solar cell including core/shell metal oxide nano-particles according to the present invention is applied to an electronic device, uniform coating of a substrate having a large area is performed to improve interface property and this assists electrons to be separate and moved efficiently. Also, application products can be selected through various types of coating methods.

The following is provided to explain the details of the present invention with examples and experimental examples, wherein, the present invention is only illustrated by the examples, thus, the present invention is not limited to the specific examples.

### Example 1

### Method I of Manufacturing a Photoactive Layer Solution Including NiO Nano-Particles Coated with TiOₓ (0.5≦x≦2)

Step 1. Coating NiO with TiOₓ

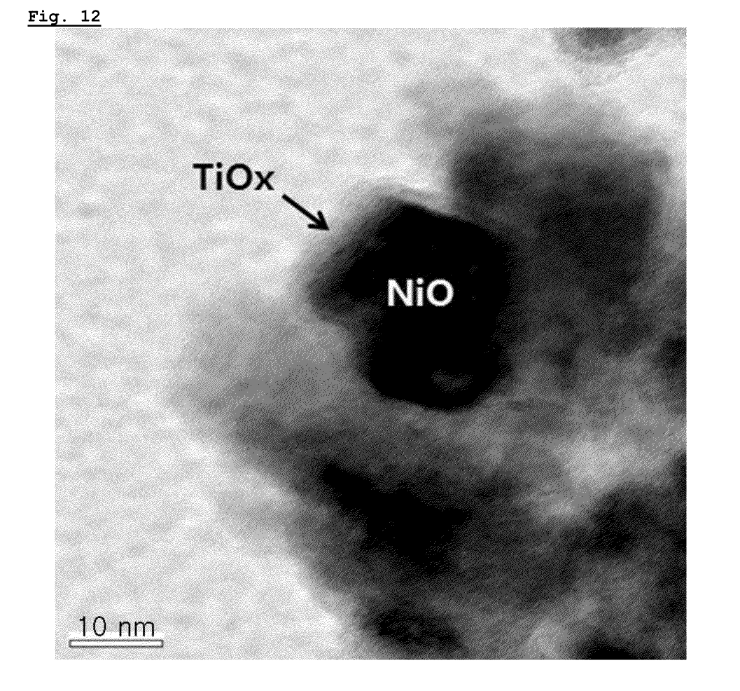

0.3 g of NiO nano-particles were inserted into a fixing device for atomic layer deposition (ALD) and the fixing device was placed in atomic deposition reactor to perform powder-type atomic layer deposition. 80° C. of a titanium precursor (Ti(OCH(CH₃)₂)₄) was provided to a primary precursor along with carrier gas, nitrogen (N₂, 50 sccm), under vacuum condition to perform saturated surface reaction on the NiO nano-particles for 60 sec and the remained titanium precursor which did not reacted with the provided nitrogen gas was removed with purge gas. Then, distilled water at room temperature was provided into a secondary precursor along with carrier gas, nitrogen (N₂), for 30 sec and the secondary precursor was reacted with a titanium precursor on the surface of the provided NiO nano-particles to coat titanium oxide. At this time, the temperature of ALD was 150° C. The remained distilled water which did not reacted with provided nitrogen gas was removed with purge gas and 0.3 g of NiO coated with TiOₓ was obtained. Uniformly formed TiOₓ film on the surface of NiO nano-particles was confirmed with TEM and the result is presented in FIG. 12.

Step 2. Dispersing NiO/TiOₓ into a Dispersion Solution

20 mg of NiO (NiO/TiOₓ) nano-particles coated with TiOₓ manufactured in step 1) was added into 5 mL of dichlorobenzene and dispersed with an ultrasonic device.

Step 3. Adding the Solution Dispersed NiO/TiOₓ into a Mixture of P3HT and PCBM

0.5 mL of the NiO/TiOₓ dispersion solution of step 2) was added and mixed into 0.5 mL of a solution in which P3HT and PCBM were mixed at 1:1 ratio to manufacture a photoactive layer solution including NiO nano-particles coated with TiOₓ.

### Example 2

### Method II of Manufacturing Photoactive Layer Solution Including NiO Nano-Particles Coated with TiOₓ

Except that 10 mg of NiO/TiOₓ nano-particles were dispersed into 5 mL of dichlorobenzene in step 2) of Example 1, a photoactive layer solution including NiO nano-particles coated with TiOₓ was manufactured according to the method of Example 1.

### Example 3

### Method III of Manufacturing Photoactive Layer Solution Including NiO Nano-Particles Coated with TiOₓ

Except that 5 mg of NiO/TiOₓ nano-particles was dispersed in 5 mL of dichlorobenzene in step 3) of Example 1, a photoactive layer solution including NiO nano-particles coated with TiOₓ was manufactured according to the method of Example 1.

### Example 4

### Method IV of Manufacturing Photoactive Layer Solution Including NiO Nano-Particles Coated with TiOₓ

Except that 2.5 mg of NiO/TiOₓ nano-particles was dispersed in 5 mL of dichlorobenzene in step 2) of Example 1, a photoactive layer solution including NiO nano-particles coated with TiOₓ was manufactured according to the method of Example 1.

### Example 5

### Method V of Manufacturing Photoactive Layer Solution Including NiO Nano-Particles Coated with TiOₓ

Except for a difference of using a mixture in which P3HT and PCBM were mixed at 1:0.8 ratios in step 3) in Example 2, a photoactive layer solution including NiO nano-particles coated with TiOₓ was manufactured according to the method of Example 2.

### Example 6

### Method VI of Manufacturing Photoactive Layer Solution Including NiO Nano-Particles Coated with TiOₓ

Except for a difference of using a mixture in which P3HT and PCBM were mixed at 1:1.2 ratios in step 3) in Example 2, a photoactive layer solution including NiO nano-particles coated with TiOₓ was manufactured according to the method of Example 2.

### Example 7

### Method VII of Photoactive Layer Solution Including NiO Nano-Particles Coated with TiOₓ

Except for a difference of using a mixture in which P3HT and PCBM were mixed at 1:1.4 ratios in step 3) in Example 2, a photoactive layer solution including NiO nano-particles coated with TiOₓ was manufactured, according to the method of Example 2.

### Example 8

### Method I of Manufacturing an Organic Solar Cell Including Photoactive Layer Solution Having NiO/TiOₓ Nano-particles

Step a. Coating Transparent Substrate with Transparent Conductive Oxide

ITO is layered on a glass substrate through sputtering process.

Step b. Coating the Substrate of Step a) with a Photoactive Layer Solution Including NiO/TiOₓ Nano-Particles

The glass substrate layered ITO in step a) was coated with the photoactive layer solution manufactured in Example 1 by spin coating. The spin coating was performed 600 rpm, 60 sec, and the photoactive layer was coated in 250 nm thickness.

Step c. Drying the Photoactive Layer

The coated photoactive layer of step b) was dried for 2 hrs at room temperature.

Step d. Performing Heat Treatment for the Dried Substrate

The substrate dried in step c) was heated on 150° C. hot plate for 20 min.

Step e. Depositing LiF/Al on the Heat Treated Substrate

LiF was deposited on the heat treated substrate of step d) with thermal evaporator to have 1 nm thickness and then 100 nm of Al was deposited thereon. Accordingly, an organic solar cell including a photoactive layer solution including NiO/TiOₓ nano-particles was manufactured.

### Example 9

### Method II of Manufacturing an Organic Solar Cell Including Photoactive Layer Solution Having NiO/TiOₓ Nano-Particles

Except for a difference of using the photoactive layer solution manufactured in Example 2, an organic solar cell including photoactive layer solution having NiO/TiOₓ nano-particles was manufactured according to the method to Example 8.

### Example 10

### Method III of Manufacturing an Organic Solar Cell Including Photoactive Layer Solution Having NiO/TiOₓ Nano-Particles

Except for a difference of using the photoactive layer solution manufactured in Example 3, an organic solar cell including photoactive layer solution having NiO/TiOₓ nano-particles was manufactured, according to the method to Example 8.

### Example 11

### Method IV of Manufacturing an Organic Solar Cell Including Photoactive Layer Solution Having NiO/TiOₓ Nano-Particles

Except for a difference of using the photoactive layer solution manufactured in Example 4, an organic solar cell including photoactive layer solution having NiO/TiOₓ nano-particles was manufactured according to the method to Example 8.

### Example 12

### Method V of Manufacturing Organic Solar Cell Including Photoactive Layer Solution Having NiO/TiOₓ Nano-Particles

Except for a difference of using the photoactive layer solution manufactured in Example 5, an organic solar cell including photoactive layer solution having NiO/TiOₓ nano-particles was manufactured according to the method to Example 8.

### Example 13

### Method VI of Manufacturing Organic Solar Cell Including Photoactive Layer Solution Having NiO/TiOₓ Nano-Particles

Except for a difference of using the photoactive layer solution manufactured in Example 6, an organic solar cell including photoactive layer solution having NiO/TiOₓ nano-particles was manufactured according to the method to Example 8.

### Example 14

### Method VII of Manufacturing Organic Solar Cell Including Photoactive Layer Solution Having NiO/TiOₓ Nano-Particles

Except for a difference of using the photoactive layer solution manufactured in Example 7, an organic solar cell including photoactive layer solution having NiO/TiOₓ nano-particles was manufactured according to the method to Example 8.

### Example 15

### Method VIII of Manufacturing Organic Solar Cell Including Photoactive Layer Solution Having NiO/TiOₓ Nano-Particles

Except for a difference of manufacturing 170 nm thickness of photoactive layer by spin coating with 800 rpm, an organic solar cell including photoactive layer solution having NiO/TiOₓ nano-particles was manufactured according to the method to Example 9.

### Comparative Example 1

### Method of Manufacturing Organic Solar Cell Including Photoactive Layer Solution without having NiO/TiOₓ Nano-Particles

Except for a difference of using the photoactive layer solution without having NiO/TiOₓ nano-particles, an organic solar cell was manufactured according to the method of Example 8.

### Comparative Example 2

### Method of Manufacturing Organic Solar Cell Including NiO Nano-Particles which are not Treated with Heat

Except for a difference of using the photoactive layer solution in which 20 mg of untreated heat-NiO nano-particles was dispersed into 5 mL of dichlorobenzene, an organic solar cell was manufactured according to the method of Example 8.

### Comparative Example 3

### Method I of Manufacturing Organic Solar Cell Including Heat Treated NiO Nano-Particles

Except for a difference of using the photoactive layer solution in which 20 mg of NiO nano-particles treated with 150° C. heat was dispersed into 5 mL of dichlorobenzene, an organic solar cell was manufactured according to the method of Example 8.

### Comparative Example 4

### Method II of Manufacturing an Organic Solar Cell Including Heat Treated NiO Nano-Particles

Except for a difference of using the photoactive layer solution in which 10 mg of NiO nano-particles treated with 150° C. heat was dispersed into 5 mL of dichlorobenzene, an organic solar cell was manufactured according to the method of Example 8.

### Comparative Example 5

### Method III of Manufacturing Organic Solar Cell Including Heat Treated NiO Nano-Particles

Except for a difference of using the photoactive layer solution in which 5 mg of NiO nano-particles treated with 150° C. heat was dispersed into 5 mL of dichlorobenzene, an organic solar cell was manufactured according to the method of Example 8.

### Comparative Example 6

### Method Iv of Manufacturing Organic Solar Cell Including Heat Treated NiO Nano-Particles

Except for a difference of using the photoactive layer solution in which 2.5 mg of NiO nano-particles treated with 150° C. heat was dispersed into 5 mL of dichlorobenzene, according to the method of Example 8, an organic solar cell was manufactured.

### Comparative Example 7

### Method of Manufacturing Organic Solar Cell Including PEDOT:PSS

After performing step a) of Example 8, PEDOT:PSS layer was layered to 40 nm thickness by spin coating and the NiO/TiOₓ was not included in photoactive layer solution in step b) of Example 8. Except this, an organic solar cell was manufactured according to the method of Example 8.

### Experimental Example 1

### Property Evaluation I of Organic Solar Cell

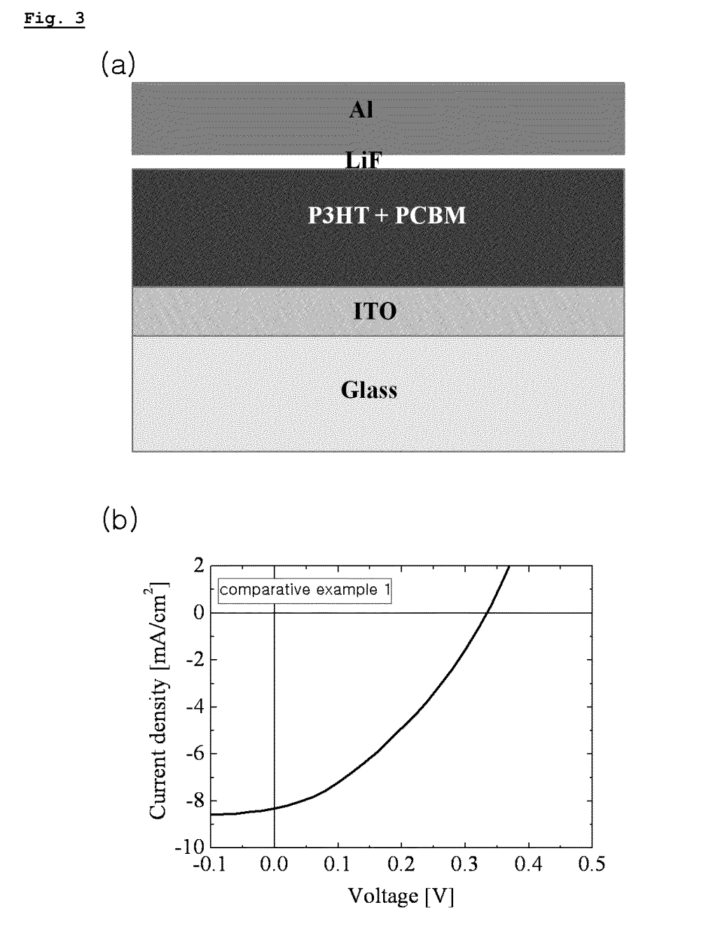

An experiment was performed in order to evaluate the organic solar cell manufactured in Comparative Example 1 and the result is presented in FIG. 3 and Table 1.

For this evaluation, Keithley 2400 was used to confirm the photoelectric current density-voltage (J-V) curve, and solar simulator (Pecell Technologies Inc., PEC-L11) was used as a source of illumination. Under AM 1.5G, 100 mW/cm² of light was illuminated to measure short circuit current (Jsc), open circuit voltage (Voc), fill factor (FF) and photoelectric conversion efficiency (PEC).

FIG. 3(a) presents a mimetic diagram illustrating the organic solar cell manufactured in Comparative Example 1; FIG. 3(b) presents a graph based on the values obtained from the experiment with respect to Comparative Example 1. Short circuit current value is a current value when voltage is 0; open circuit voltage value is a voltage value when current density is 0; FF value is obtained after multiplying current density and voltage values at the point that electricity is maximized, the sum of multiplation is divided with multiplation value of Voc and Jsc; and PEC value is calculated with Keithley 2400. The result of FIG. 3(b) is organized and presented in Table 1.

TABLE 1

| | Jsc(mW/cm²) | Voc (V) | FF | PCE (%) |
|---|---|---|---|---|
| Example 9 | 8.76 | 0.52 | 0.56 | 2.58 |
| Comparative | 8.32 | 0.33 | 0.35 | 0.98 |
| Example 1 | | | | |

Referring to Table 1, as compared the values of Example 9 and Comparative Example 1, it is recognized that VoC and FF values of Comparative Example 1 are smaller than the values of Example 9. Also, photoelectric conversion energy efficiency value of Example 9 (i.e., 2.58%) is much higher than the one of Comparative Example 1 (i.e., approximately 1%). Accordingly, it is confirmed that an organic solar cell using a photoactive layer solution including NiO nano-particles coated with TiOₓ shows better efficiency.

### Experimental Example 2

### Property Evaluation II of Organic Solar Cell

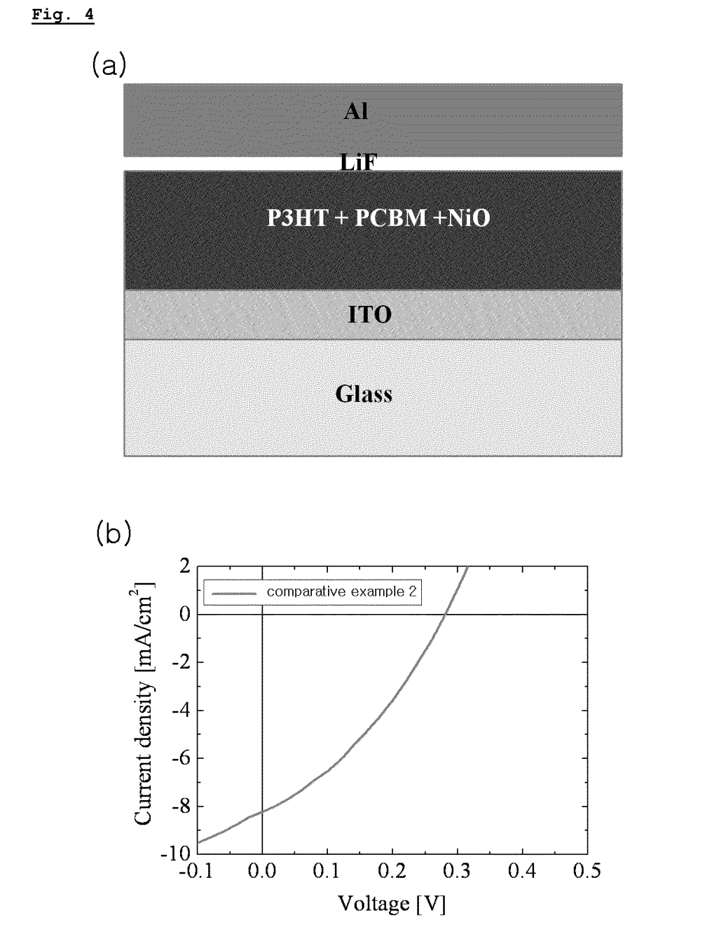

According to the method of Example 1, an experiment was performed in order to evaluate the organic solar cell manufactured in Comparative Example 2 and the result is presented in FIG. 4 and Table 2.

FIG. 4(a) presents a mimetic diagram illustrating the organic solar cell manufactured in Comparative Example 2; FIG. 4(b) presents a graph based on the values obtained from the experiment with respect to Comparative Example 2. Short circuit current value is a current value when voltage is 0; open circuit voltage value is a voltage value when current density is 0; FF value is obtained after multiplying current density and voltage values at the point that electricity is maximized, the sum of multiplation is divided with multiplation value of Voc and Jsc; and PEC value is calculated with Keithley 2400. The result of FIG. 4(b) is organized and presented in Table 2.

TABLE 2

| | Jsc(mW/cm²) | Voc (V) | FF | PCE (%) |
|---|---|---|---|---|
| Example 9 | 8.76 | 0.52 | 0.56 | 2.58 |
| Comparative | 8.24 | 0.28 | 0.34 | 0.78 |
| Example 2 | | | | |

Comparative Example 2 was performed to add untreated heat-NiO nano-particles into a solution having P3HT:PCBM=1.0:1.0. Such as Comparative Example 1, it is recognized that the FF and Voc values of Comparative Example 2 is significantly smaller than the values of Example 9.

### Experimental Example 3

### Property Evaluation III of Organic Solar Cell

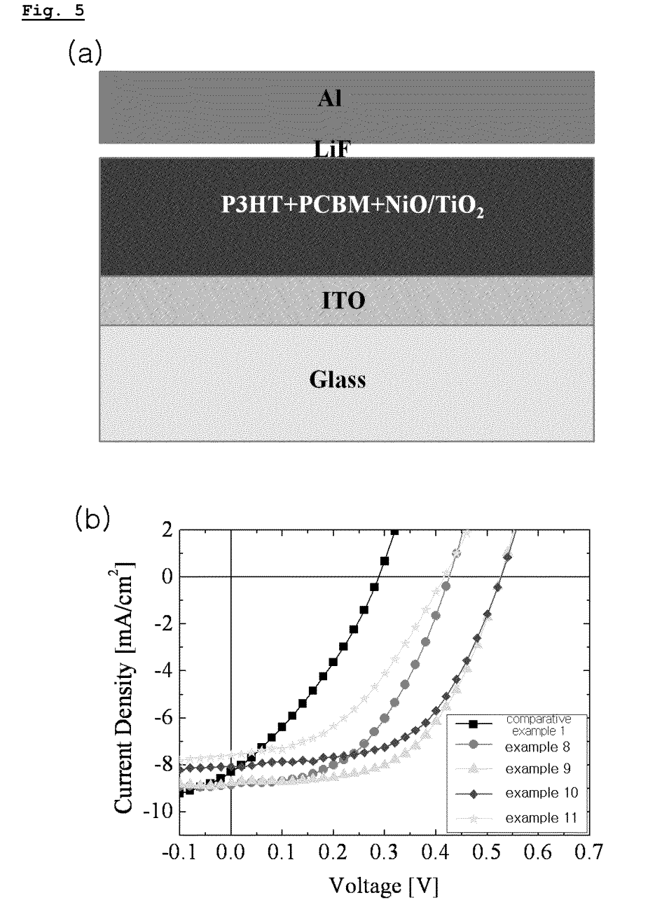

According to the method of Comparative Example 1, an experiment was performed in order to evaluate property of the organic solar cell manufactured in Examples 8 to 11 and Comparative Example 1, and to confirm the effect of NiO/TiOₓ content on an organic solar cell. The result is presented FIG. 5 and Table 3.

FIG. 5(a) presents a mimetic diagram illustrating the organic solar cells manufactured in Examples 8 to 11; FIG. 5(b) presents a graph based on the values obtained from the experiments with respect to Examples 8 to 11. Short circuit current value is a current value when voltage is 0; open circuit voltage value is a voltage value when current density is 0; FF value is obtained after multiplying current density and voltage values at the point that electricity is maximized, the sum of multiplation is divided with multiplation value of Voc and Jsc; and PEC value is calculated with Keithley 2400. The result of FIG. 5(b) is organized and presented in Table 3.

TABLE 3

| Contents | Jsc | | | | Rs |
|---|---|---|---|---|---|
| (mg/ml) | (mW/cm²) | Voc (V) | FF | PCE (%) | (Ω · cm²) |
| Comparative | 8.46 | 0.59 | 0.66 | 3.31 | 5.1 |
| Example 7 | | | | | |
| Comparative | 8.30 | 0.28 | 0.32 | 0.77 | 19.2 |
| Example 1 | | | | | |
| Example 8 | 8.85 | 0.43 | 0.49 | 1.85 | 18.1 |
| Example 9 | 8.76 | 0.52 | 0.56 | 2.58 | 4.8 |
| Example 10 | 8.07 | 0.52 | 0.55 | 2.35 | 6.5 |
| Example 11 | 7.59 | 0.41 | 0.42 | 1.34 | 6.95 |

The experiment measured property of an organic solar cell by changing the content of NiO/TiOₓ nano-particles. When the content of NiO/TiOₓ nano-particles was decreased, even though short circuit current value was decreased, the highest values of Voc and FF were presented in Example 9. Also, an ohmic resistance value which was in inverse proportion to a PCE value had the smallest values in Example 9; therefore, it was confirmed that the property of an organic solar cell could be change depending on the content of NiO/TiOₓ nano-particles.

### Experimental Example 4

### Property Evaluation IV of Organic Solar Cell

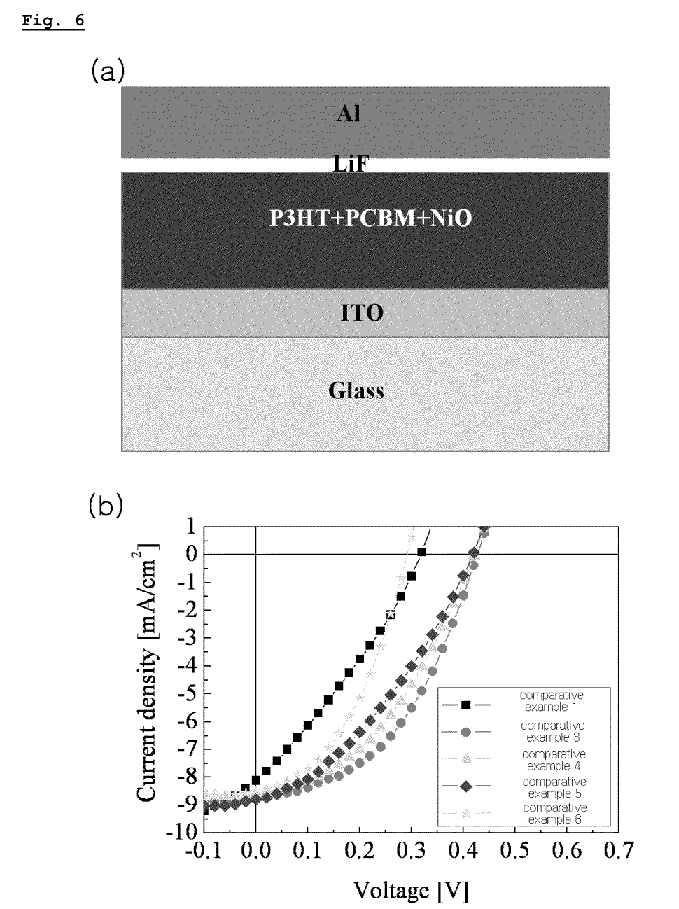

According to the method of Example 1, an experiment was performed in order to evaluate property of the organic solar cell manufactured in Comparative Examples 1 and 3 to 6, and to confirm the effect of NiO nano-particle content and heat treated NiO on an organic solar cell. The result is presented FIG. 6 and Table 4.

FIG. 6(a) presents a mimetic diagram illustrating the organic solar cells manufactured in Comparative Examples 3-6; FIG. 6(b) presents a graph based on the values obtained from the experiments with respect to Comparative Examples 1 and 3 to 6. Short circuit current value is a current value when voltage is 0; open circuit voltage value is a voltage value when current density is 0; FF value is obtained after multiplying current density and voltage values at the point that electricity is maximized, the sum of multiplation is divided with multiplation value of Voc and Jsc; and PEC value is calculated with Keithley 2400. The result of FIG. 6(b) is organized and presented in Table 4.

TABLE 4

| Heat treated | | | | | |
|---|---|---|---|---|---|
| NiO content | Jsc | | | | Rs |
| (mg/mL) | (mW/cm²) | Voc (V) | FF | PCE (%) | (Ω · cm²) |
| Comparative | 8.11 | 0.31 | 0.29 | 0.76 | 27.4 |
| Example 1 | | | | | |
| Comparative | 8.77 | 0.42 | 0.45 | 1.69 | 17.2 |
| Example 3 | | | | | |
| Comparative | 8.55 | 0.42 | 0.41 | 1.49 | 35.2 |
| Example 4 | | | | | |
| Comparative | 8.79 | 0.41 | 0.36 | 1.32 | 11.78 |
| Example 5 | | | | | |
| Comparative | 8.50 | 0.29 | 0.42 | 1.04 | 11.4 |
| Example 6 | | | | | |

The Comparative Examples 3 to 6 were heat-treated at 150° C. of heat, which was identical to the temperature of an ALD device used in the manufacturing process of NiO/TiOₓ nano-particles. Referring to Table 4, NiO content affects the result of Comparative Examples 3 to 6 and the resistance values thereof are far high as compared to those of Example 9. Accordingly, it was confirmed that NiO cannot solely act as a P buffer layer.

### Experimental Example 5

### Property Evaluation V of Organic Solar Cell

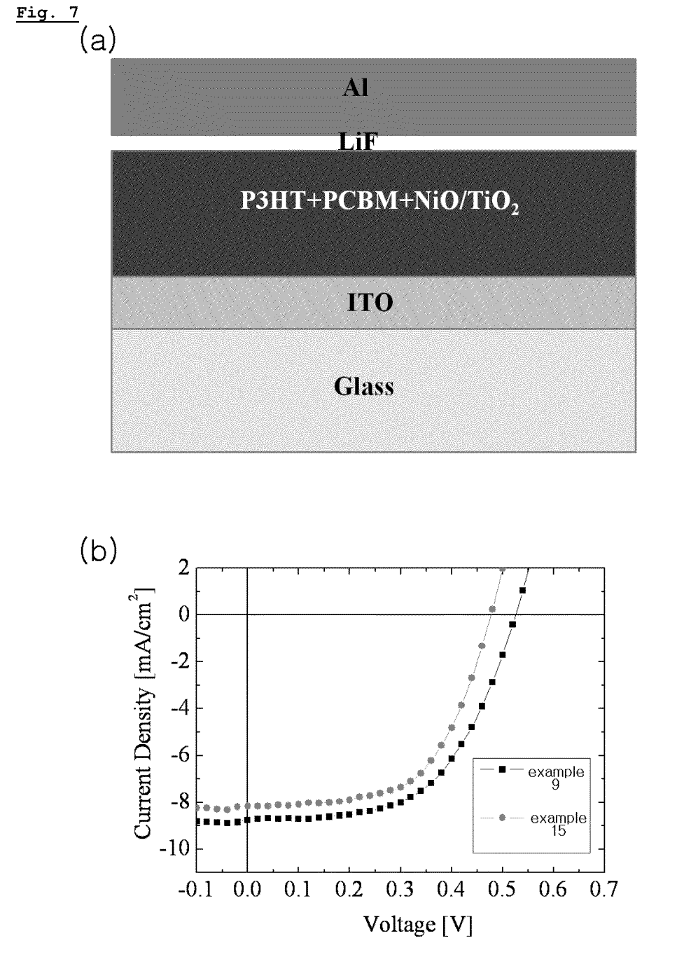

According to the method of Example 1, an experiment was performed in order to evaluate property of the organic solar cell manufactured in Examples 9 and 15, and to confirm the effect of thickness of a photoactive layer on an organic solar cell. The result is presented FIG. 7 and Table 5.

FIG. 7(a) presents a mimetic diagram illustrating the organic solar cells manufactured in Examples 9 and 15; FIG. 7(b) presents a graph based on the values obtained from the experiments with respect to Examples 9 and 15. Short circuit current value is a current value when voltage is 0; open circuit voltage value is a voltage value when current density is 0; FF value is obtained after multiplying current density and voltage values at the point that electricity is maximized, the sum of multiplation is divided with multiplation value of Voc and Jsc; and PEC value is calculated with Keithley 2400. The result of FIG. 7(b) is organized and presented in Table 5.

TABLE 5

| Spin speed | Jsc | | | | Rs |
|---|---|---|---|---|---|
| (rpm) | (mW/cm²) | Voc (V) | FF | PCE (%) | (Ω · cm²) |
| Example 9 | 8.76 | 0.52 | 0.56 | 2.58 | 4.8 |
| (600) | | | | | |
| Example 15 | 8.16 | 0.47 | 0.59 | 2.29 | 7.3 |
| (800) | | | | | |

When spin coating was used to manufacture an organic solar cell, thickness of film related to spin speed, so that faster speed caused to create thinner film. Referring to Table 5, when spin speed was 600 rpm, 250 nm thickness of film was created and when spin speed was 800 rpm, 170 nm thickness of film was created. Also, as regarding the property of the organic solar cells, Example 9 having lower spin speed (i.e., 600 rpm) had higher values in all area except FF and Rs. Accordingly, it was confirmed that if thickness of photoactive layer was increased, an organic solar cell with more improved efficiency could be manufactured.

### Experimental Example 6

### Property Evaluation VI of Organic Solar Cell

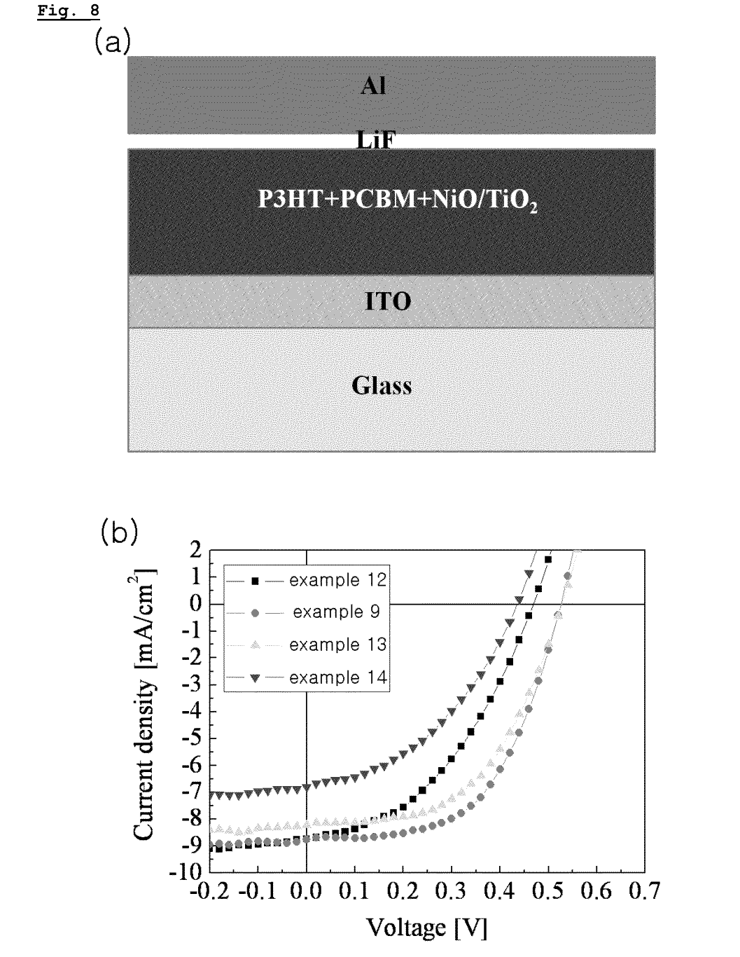

According to the method of Comparative Example 1, an experiment was performed in order to evaluate property of the organic solar cell manufactured in Examples 9 and 12-14, and to confirm the effect of P3HT:PCBM ratio on an organic solar cell. The result is presented FIG. 8 and Table 6.

FIG. 8(a) presents a mimetic diagram illustrating the organic solar cells manufactured in Examples 9 and 12-14; FIG. 8(b) presents a graph based on the values obtained from the experiments with respect to Examples 9 and 12-14. Short circuit current value is a current value when voltage is 0; open circuit voltage value is a voltage value when current density is 0; FF value is obtained after multiplying current density and voltage values at the point that electricity is maximized, the sum of multiplation is divided with multiplation value of Voc and Jsc; and PEC value is calculated with Keithley 2400. The result of FIG. 8(b) is organized and presented in Table 6.

TABLE 6

| P3HT : | Jsc | | | |
|---|---|---|---|---|
| PCBM | (mW/cm²) | Voc (V) | FF | PCE(%) |
| Example 12 | 8.75 | 0.46 | 0.42 | 1.73 |
| (1:0.8) | | | | |
| Example 9 | 7.76 | 0.52 | 0.56 | 2.58 |
| (1:1.0) | | | | |
| Example 13 | 8.21 | 0.52 | 0.53 | 2.29 |
| (1:1.2) | | | | |
| Example 14 | 6.80 | 0.43 | 0.41 | 1.23 |
| (1:1.4) | | | | |

Referring to Table 6, it is recognized that Example 9 in which the ratio of P3HT:PCBM is 1.0:1.0 has not only smaller Jsc value but also larger Voc and FF than others, and that Example 13 with the ratio 1:1.2 has similar values to those of Example 9 except Jsc value.

### Experimental Example 7

### Observation of Photoactive Layer Distribution

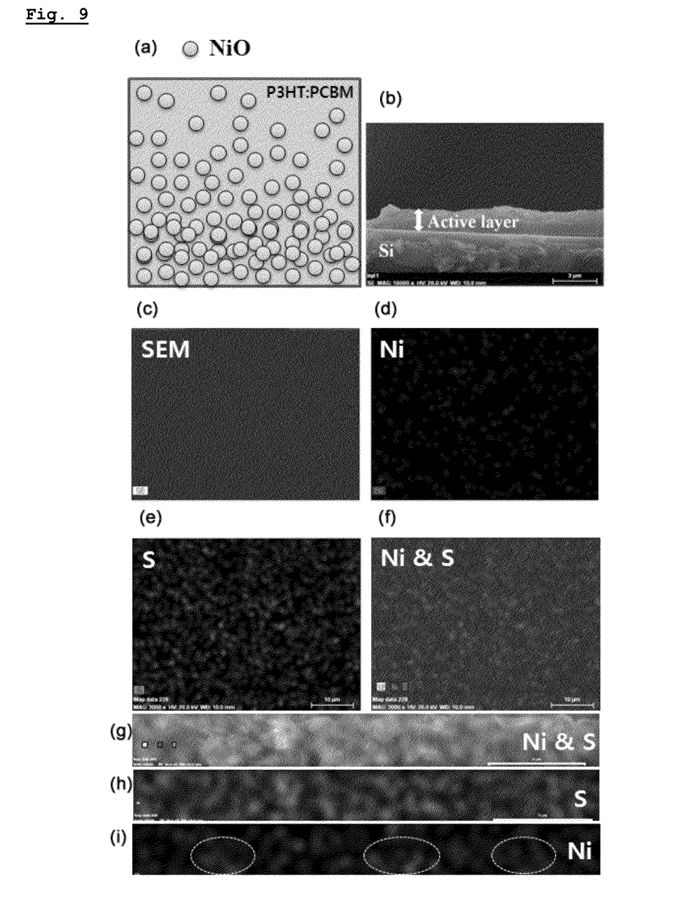

In order to observe P3HT and PCBM and distribution of NiO coated with TiOₓ on the photoactive layer, the photoactive layer solution manufactured in Example 2 was layered on a Si substrate and then, SEM and EDX mapping was performed. The result is presented in FIG. 9.

Referring to FIG. 9, FIG. 9(a) presents a mimetic diagram illustrating uniformly distributed NiO/TiOₓ on P3HT and PCBM. The mimetic diagram was achieved according to the following analysis. First, through SEM image, FIG. 9(b) presents cross-sectional view of a Si substrate which photoactive layer is coated thereon. FIG. 9(c) presents a magnified image of FIG. 9(b) and FIG. 9(d)-(i) presents the EDX mapping results of the area in FIG. 9(c). Referring to FIG. 9(d), presence of Ni is confirmed. That is, core/shell structured NiO of photoactive layer has metal oxide nano-particles. However, FIG. 9(d)-(i) show the absence of TiOₓ which is coated on NiO because titanium oxide is coated as a monolayer and this is too thin to be analyzed. FIG. 9(e) shows existence of S since the S is contained within P3HT and PCBM. Also, as performing EDX mapping of Ni and S simultaneously, it is recognized that nickel oxide nano-particles coated with titanium oxide are uniformly dispersed in a photoactive layer solution.

### Experimental Example 8

### Analysis of X-Ray Photoelectron Spectroscopy

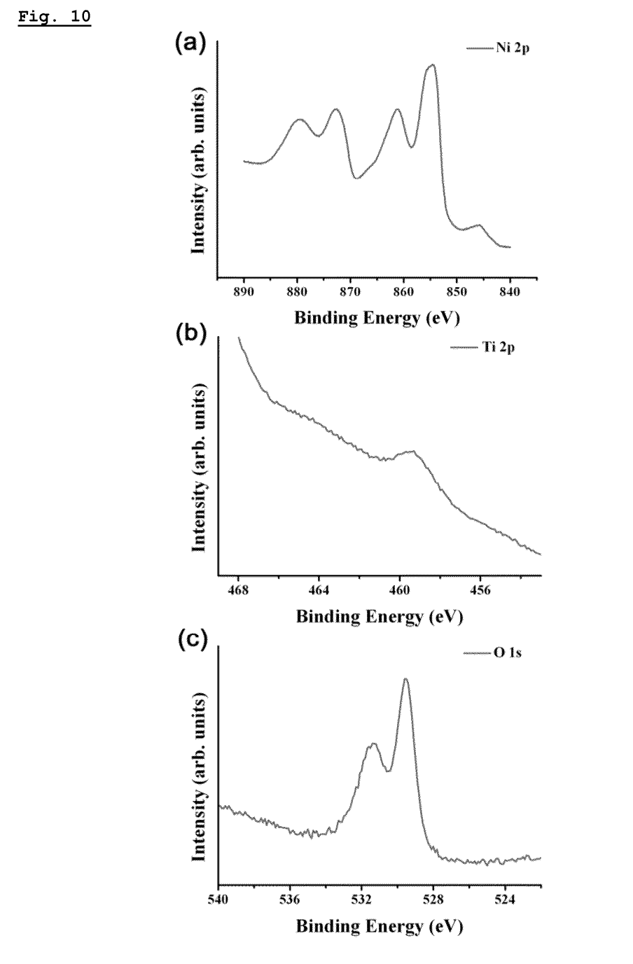

Regarding the NiO coated with TiOₓ and manufactured in step 1) of Example 1, X-ray photoelectron spectroscopy (XPS) was used to confirm presence of the coating and the result is presented in FIG. 10.

Referring to FIG. 10, it is confirmed that NI, Ti, O are existed therein and the result shows TiOₓ is well deposited through ALD process.

The foregoing exemplary embodiments and advantages are merely exemplary and are not to be construed as limiting the present invention. The present teaching can be readily applied to other types of apparatuses. Also, the description of the exemplary embodiments of the present inventive concept is intended to be illustrative, and not to limit the scope of the claims, and many alternatives, modifications, and variations will be apparent to those skilled in the art.

What is claimed is:

1. A method of manufacturing a photoactive layer solution for an efficient organic solar cell including core/shell metal oxide nano-particles, the method comprising steps of: forming core/shell structure by coating P-type metal nano-particles with N-type metal oxide (step 1); dispersing core/shell structured P-type metal nano-particles coated with N-type metal oxide of step 1 into dispersion solution (step 2); and adding a solution with dispersed core/shell structured P-type metal nano-particles coated with N-type metal oxide of step 2 into a mixture of P3HT (Poly(3-Hexylthiophene)) and PCBM (Phenyl-C61-butyric acid methyl ester) (step 3).

2. The method according to claim 1, wherein the coating of step 1) is performed by atomic layer deposition (ALD).

3. The method according to claim 2, wherein temperature of ALD is 100-300° C.

4. The method according to claim 1, wherein concentration of the dispersion solution in which core/shell structured P-type metal nano-particles coated with N-type metal oxide is dispersed in step 2) is 0.1-20%.

5. A photoactive layer solution for an efficient organic solar cell including core/shell metal oxide nano-particles having core/shell structured P-type metal nano-particles coated with N-type metal oxide.

6. The solution according to claim 5, wherein core/shell structured P-type metal nano-particles coated with N-type metal oxide of the photoactive layer solution is NiO/TiOₓ (0.5≦x≦2).

7. An efficient organic solar cell including core/shell structured metal oxide nano-particles, the efficient organic solar cell comprising: a transparent substrate; a transparent conductive oxide (as an anode); a photoactive layer including core/shell structured P-type metal nano-particles coated with N-type metal oxide; and a metal electrode (as a cathode).

8. The efficient organic solar cell according to claim 7, thickness of the photoactive layer coating film comprising core/shell structured P-type metal nano-particles coated with N-type metal oxide is 100-400 nm.

9. A method of manufacturing an efficient organic solar cell including core/shell structured metal oxide nano-particles, the method comprising steps of: coating a transparent substrate with transparent conductive oxide (step a); coating photoactive layer including core/shell structured P-type metal nano-particles coated with N-type metal oxide on the transparent substrate which transparent conductive oxide is coated thereon in step a) (step b); drying the photoactive layer coated in step b) (step c); performing heat treatment for the substrate dried in step c) (step d); and vapor-depositing electrode on the heat treated substrate of step d) (step e).

10. The method according to claim 9, wherein the coating of step b) is performed by one method selected from the group consisting of spin coating, spray coating, dip coating and doctor blading.

11. An electronic device including a photoactive layer solution for an efficient organic solar cell having core/shell structured metal oxide nano-particles.
